(19) United States
(12) Patent Application Publication
(10) Pub. No.: US 2017/0155063 A1
(43) Pub. Date: Jun. 1, 2017

(54) ORGANIC METAL COMPOUND, ORGANIC LIGHT-EMITTING DEVICES EMPLOYING THE SAME

(71) Applicant: INDUSTRIAL TECHNOLOGY RESEARCH INSTITUTE, Hsinchu (TW)

(72) Inventors: Cheng-An WU, New Taipei City (TW); Meng-Hao CHANG, New Taipei City (TW); Bing-Huang JIANG, New Taipei City (TW); Han-Cheng YEH, Taipei City (TW); Mei-Rurng TSENG, Hsinchu City (TW); Pang-Chi HUANG, Taoyuan City (TW); Jin-Sheng LIN, Taipei City (TW); Chun-Neng KU, Tainan City (TW); Jung-Yu LIAO, Zhubei City (TW)

(73) Assignee: INDUSTRIAL TECHNOLOGY RESEARCH INSTITUTE, Hsinchu (TW)

(21) Appl. No.: 14/972,716

(22) Filed: Dec. 17, 2015

(30) Foreign Application Priority Data
Nov. 26, 2015 (TW) 104139355

(51) Int. Cl. H01L 51/00; C09K 11/06; C07F 15/00

(52) U.S. Cl. CPC H01L 51/0085; C07F 15/0033; C09K 11/06; H01L 51/5016

(57) ABSTRACT

Organic metal compounds, and organic light-emitting devices employing the same are provided. The organic metal compound has a chemical structure represented by formula (I):

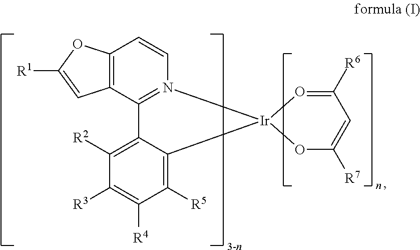

wherein each R¹ is independent and can be hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent and can be C₁₋₆ alkyl group, or phenyl group; and, n is 0 or 1.

### CROSS REFERENCE TO RELATED APPLICATIONS

The application is based on, and claims priority from, Taiwan Application Serial Number 104139355, filed on Nov. 26, 2015, the disclosure of which is hereby incorporated by reference herein in its entirety.

### TECHNICAL FIELD

The disclosure relates to an organic metal compound and an organic light-emitting device employing the same.

### BACKGROUND

An organic light-emitting diode (OLED) is a light-emitting diode employing an organic electroluminescent layer as an active layer. OLED display devices have high luminescent efficiency and long operating lifespans. In comparison with liquid-crystal displays, due to the characteristic of spontaneous emission, a device employing an organic light-emitting diode is free of a back-light source.

Generally, an organic light-emitting device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop highly efficient phosphorescent material, in order to increase the emissive efficiency of an OLED.

### SUMMARY

According to an embodiment of the disclosure, the disclosure provides an organic metal compound having a structure of Formula (I):

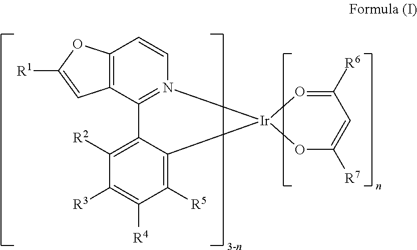

wherein, R¹ is independently hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent and can be C₁₋₆ alkyl group, or phenyl group; and, n is 0 or 1.

According to another embodiment of the disclosure, the disclosure provides an organic light-emitting device, the device includes a pair of electrodes; and an organic light-emitting element disposed between the electrodes, wherein the organic light-emitting element includes the aforementioned organic metal compound.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross section of an organic light-emitting device disclosed by an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to embodiments of the disclosure, the disclosure provides an organic metal compound having a structure of Formula (I):

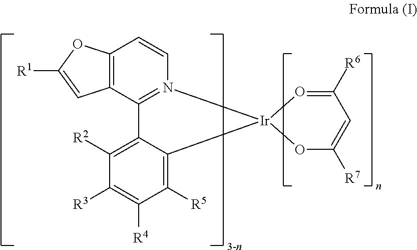

wherein, R¹ is independently hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent and can be C₁₋₆ alkyl group, or phenyl group; and, n is 0 or 1. For example, R¹ can be hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group; R², R³, R⁴, and R⁵ are independent and can be hydrogen, fluorine, methyl group, ethyl group, propyl group, isopropyl group, n-butyl group, isobutyl group, tert-butyl group, pentyl group, or hexyl group, or R³ and R⁴ are combined with the carbon atoms which they are attached to, to form a phenyl group; and, R⁶ and R⁷ are independently methyl group, ethyl group, propyl group, isopropyl group, n-butyl group, isobutyl group, tert-butyl group, pentyl group, hexyl group, or phenyl group.

According to embodiments of the disclosure, at least one of R¹, R², R³, R⁴, and R⁵ can not be hydrogen, in order to adjust the luminescent color, increase the solubility of the compound, improve the sublimation yield, and increase the luminous efficiency and lifetime of the organic light-emitting device. According to some embodiments of the disclosure, R¹ is independently hydrogen, or C₁₋₁₂ alkyl group; R², R³, R⁴, and R⁵ are independently hydrogen, halogen, C₁₋₁₂ alkyl group, or two adjacent groups of R², R³, R⁴, and R⁵ are optionally combined with the carbon atoms which they are attached to, to form an aryl group; R⁶ and R⁷ are independent C₁₋₆ alkyl group; and, n is 0 or 1.

The organic metal compounds of the disclosure can serve as a green phosphorescent dopant material, and can be applied to an organic light-emitting device for enhancing the luminous efficiency and lifetime.

According to some embodiments of the disclosure, the organic metal compound can be

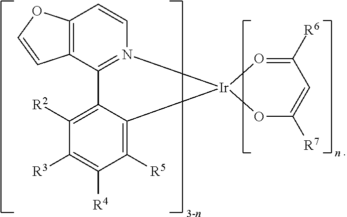

R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent C₁₋₆ alkyl group, or phenyl group; and, n is 0, or 1. For example, R², R³, R⁴, and R⁵ are independently hydrogen, fluorine, methyl group, ethyl group, propyl group, isopropyl group, n-butyl group, isobutyl group, tert-butyl group, pentyl group, or hexyl group. Furthermore, R³ and R⁴ can be combined with the carbon atoms which they are attached to, to form a phenyl group. R⁶ and R⁷ can be independently methyl group, ethyl group, propyl group, isopropyl group, n-butyl group, isobutyl group, tert-butyl group, pentyl group, hexyl group, or phenyl group. According to embodiments of the disclosure, R², R³, R⁴, and R⁵ can not be hydrogen.

According to some embodiments of the disclosure, the organic metal compound can be

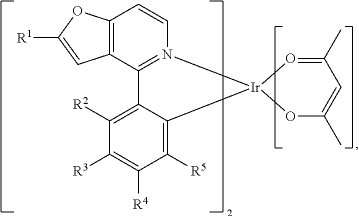

or,

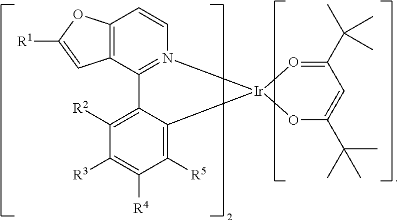

wherein, R¹ is independent and can be hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂heteroaryl group, or C₆₋₁₂ aryl group; and, R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group. For example, R¹ can be hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group. For example, R², R³, R⁴, and R⁵ are independently hydrogen, fluorine, methyl group, ethyl group, propyl group, isopropyl group, n-butyl group, isobutyl group, tert-butyl group, pentyl group, or hexyl group. Furthermore, R³ and R⁴ can be combined with the carbon atoms which they are attached to, to form a phenyl group. According to embodiments of the disclosure, R¹, R², R³, R⁴, and R⁵ can not be hydrogen.

According to some embodiments of the disclosure, the organic metal compound can be

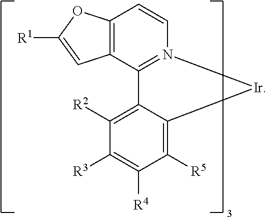

R¹ is independent and can be hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; and, R², R³, R⁴, and R⁵ are independent and can be hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group. For example, R¹ can be hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group. For example, R², R³, R⁴, and R⁵ are independently hydrogen, fluorine, methyl group, ethyl group, propyl group, isopropyl group, n-butyl group, isobutyl group, tert-butyl group, pentyl group, or hexyl group. Furthermore, R³ and R⁴ can be combined with the carbon atoms which they are attached to, to form a phenyl group. According to embodiments of the disclosure, R¹, R², R³, R⁴, and R⁵ can not be hydrogen.

For example, the organic metal compound having a structure of Formula (I) can be

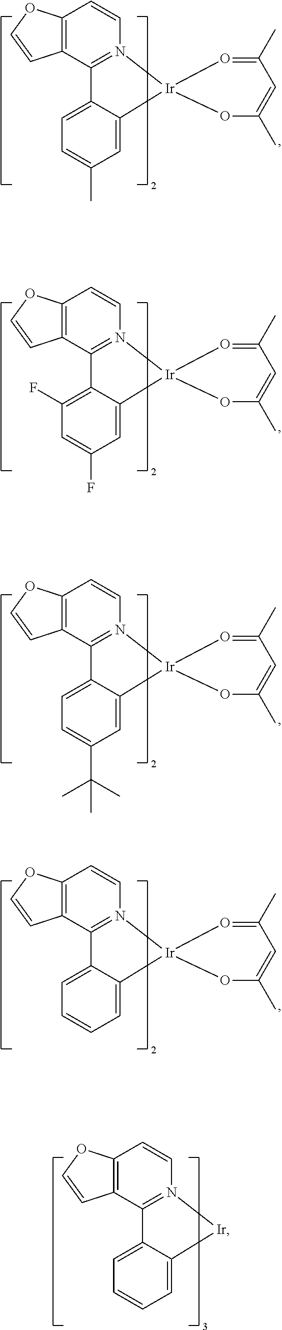

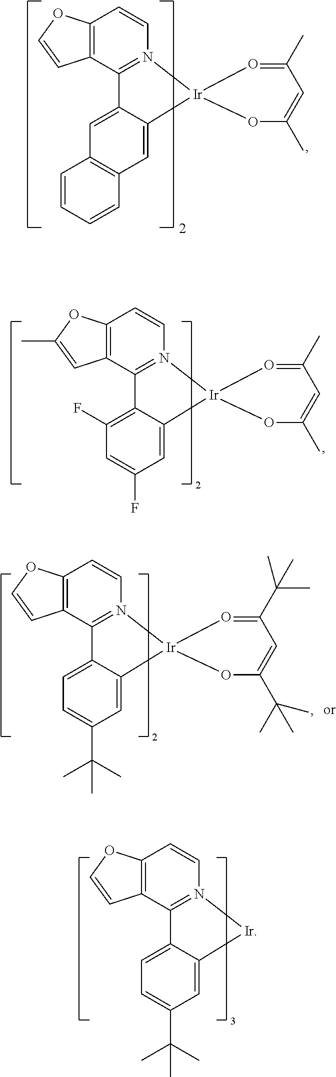

The following examples are intended to illustrate the disclosure more fully without limiting the scope, since numerous modifications and variations will be apparent to those skilled in this art.

### EXAMPLE 1

### Preparation of Organic Metal Compound (I)

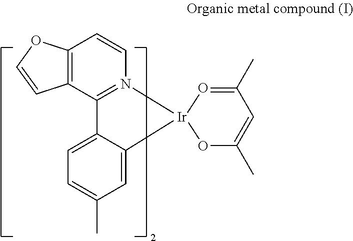

130 mmol of nitromethane, 52 mmol of 2-furfural, and 10 ml of methanol were added into a reaction bottle. Next, 130 mL of sodium hydroxide aqueous solution (1M) were dropwisely added into the reaction bottle at 0° C. After stirring at 0° C. for 15 min, the mixture was added slowly into a hydrochloric acid aqueous solution (50 ml, 8 M). Next, the reaction was terminated after being checked by thin layer chromatography (TLC), and the result was added into a reaction bottle with CH₂Cl₂ and brine. After extracting, the organic phase was collected. Next, an organic phase was separated and concentrated, and then dried by anhydrous magnesium sulfate. Finally, the result was purified by column chromatography with petroleum ether and ethyl acetate, obtaining Compound (I) with a yield of 93%. The synthesis pathway of the above reaction was as follows:

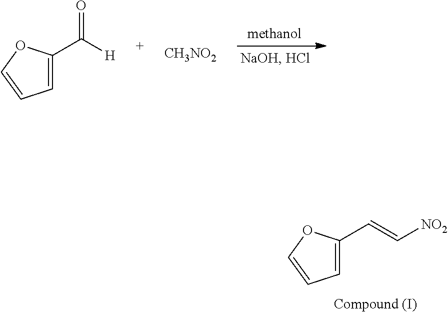

The physical measurement of the compound (I) is listed below: ¹H-NMR (200 MHz, CDCl₃, δ): 7.77 (d, 1H), 7.59 (s, 1H), 7.53 (d, 1H), 6.89 (d, 1H), 6.57 (dd, 1H).

Next, 30 ml of ethyl ether and 81 mmol of lithium aluminium hydride were added into a reaction bottle. After stirring at 0° C., 27 mmol of compound (I) and 50 ml of ethyl ether was added slowly into the reaction bottle at 0° C. After stirring for 10 min, the reaction bottle was heated to room temperature and then heated to reflux for 8 hr. Next, the reaction bottle was cooled to 0° C., and then water was added slowly to quench reaction. Next, sodium hydroxide aqueous solution (10 wt %) was added into the reaction bottle. After diluting with ethyl ether, filtrating, and concentrating, compound (II) is obtained. The synthesis pathway of the above reaction was as follows:

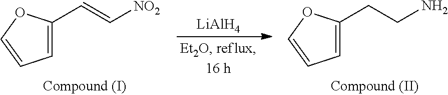 [SMILES: O=[N+]([O-])/C=C/c1ccco1 ; "LiAlH4" ; NCCc1ccco1]

Next, 55.1 mmol of compound (II), and 200 ml of water were added into a reaction bottle. Next, 82.5 mmol of 4-methylbenzoyl chloride was added into the reaction bottle at 0° C. After the addition was complete, sodium hydroxide aqueous solution (20 wt %) was added into the reaction bottle. After stirring for 8 hr and filtrating, compound (III) was obtained. The synthesis pathway of the above reaction was as follows:

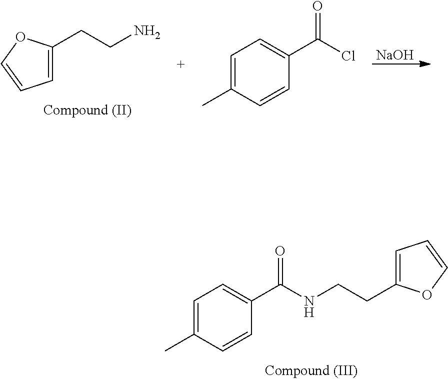

Next, 10 mmol of compound (III), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (IV) was obtained. The synthesis pathway of the above reaction was as follows:

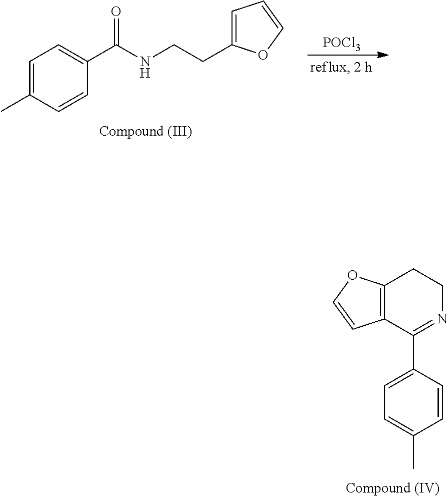

Next, 10 mmol of Compound (IV), 0.5 g of palladium 10% on carbon (Pd/C catalyst), and 100 ml of toluene were added into a reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (V) with a yield of 92%. The synthesis pathway of the above reaction was as follows:

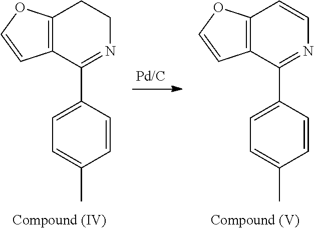 [SMILES: Cc1ccc(C2=NCCc3occc32)cc1 ; Cc1ccc(-c2nccc3occc23)cc1]

The physical measurement of the Compound (V) is listed below: ¹H-NMR (200 MHz, CDCl₃, δ): 8.56-8.53 (d, 1H), 7.86-7.82 (d, 2H), 7.66-7.65 (m, 1H), 7.39-7.36 (d, 1H), 7.33-7.29 (d, 2H), 7.05-7.04 (m, 1H), 2.42 (s, 3H).

Next, 1.54 mmol of Compound (V), iridium trichloride (IrCl₃) (0.7 mmol), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining Compound (VI). The synthesis pathway of the above reaction was as follows:

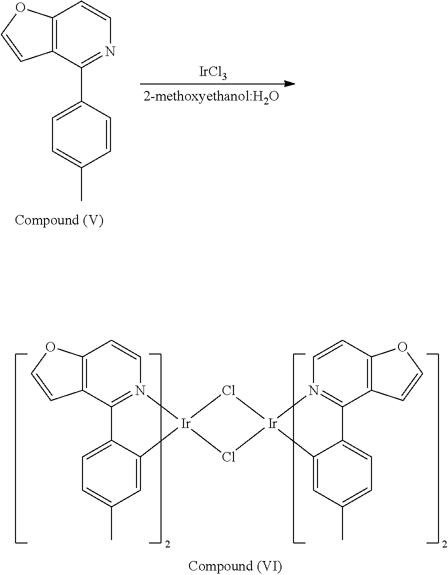

Next, 1 mmol of Compound (VI), 3 mmol of acetylacetone, 2 mmol of sodium carbonate, and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (I) with a yield of 50%. The synthesis pathway of the above reaction was as follows:

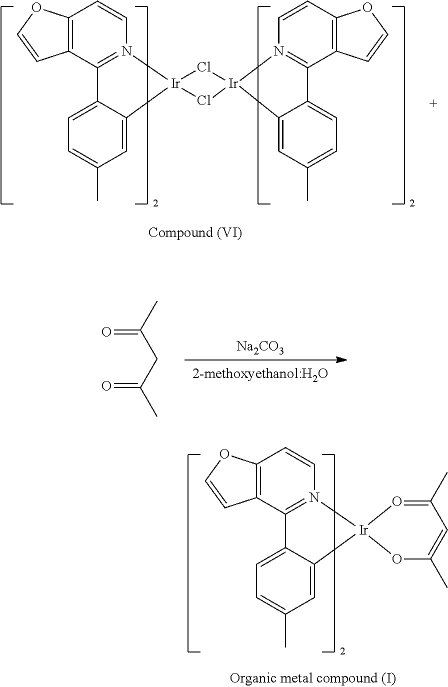

The physical measurement of Organic metal compound (I) is listed below: ¹H-NMR (200 MHz, CDCl₃, δ): 8.40-8.37 (d, 2H), 7.83-7.79 (m, 4H), 7.51-7.50 (s, 2H), 7.32-7.28 (d, 2H), 6.70-6.66 (d, 2H), 6.09 (s, 2H), 5.19 (s, 1H), 2.03 (s, 6H), 1.75 (s, 6H).

### EXAMPLE 2

### Preparation of Organic Metal Compound (II)

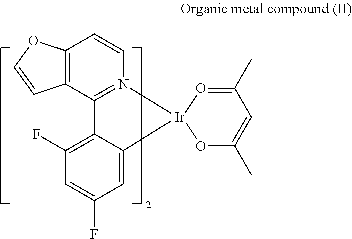

First, 55.1 mmol of Compound (II), and 200 ml of water were added into a reaction bottle. Next, 82.5 mmol of 2,4-difluorobenzoyl chloride was added into the reaction bottle at 0° C. After the addition was complete, sodium hydroxide aqueous solution (20 wt %) was added into the reaction bottle. After stirring for 8 hr, the mixture was filtrated, obtaining Compound (VII). The synthesis pathway of the above reaction was as follows:

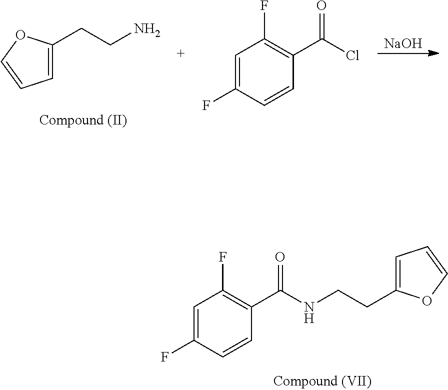

Next, 10 mmol of Compound (VII), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (VIII) was obtained. The synthesis pathway of the above reaction was as follows:

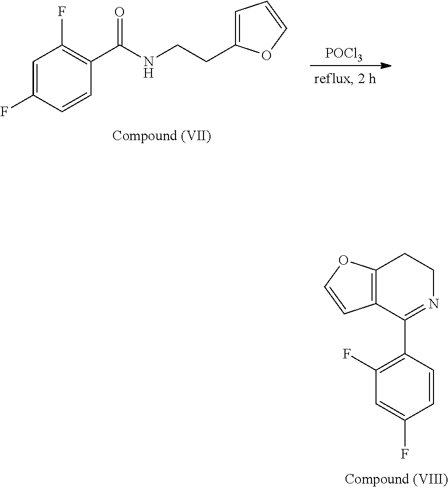

Next, 10 mmol of Compound (VIII), 0.5 g of palladium 10% on carbon (Pd/C catalyst), and 100 ml of toluene were added into the reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (IX) with a yield of 95%. The synthesis pathway of the above reaction was as follows:

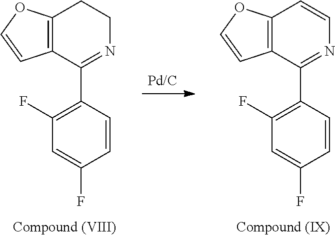 [SMILES: Fc1ccc(C2=NCCc3occc32)c(F)c1 ; Fc1ccc(-c2nccc3occc23)c(F)c1]

The physical measurement of Compound (IX) is listed below: ¹H-NMR (200 MHz, CDCl₃, δ): 8.61-8.58 (d, 1H), 7.84-7.72 (m, 1H), 7.70-7.68 (d, 1H), 7.49-7.46 (d, 1H), 7.09-6.92 (m, 2H), 6.83-6.80 (m, 1H)

Next, Compound (IX) (1.54 mmol), and 0.7 mmol of iridium trichloride (IrCl₃), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining (X). The synthesis pathway of the above reaction was as follows:

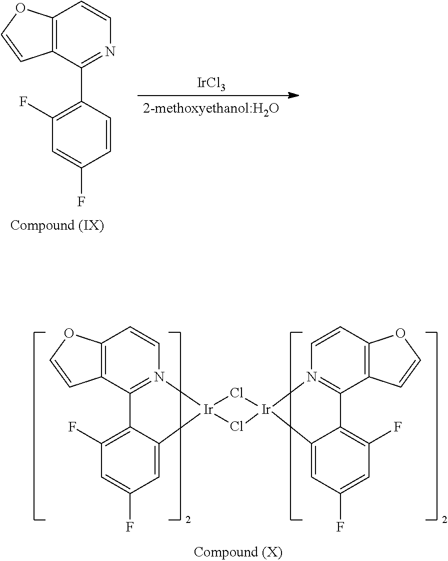

Next, 1 mmol of Compound (X), 3 mmol of acetylacetone, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (II) with a yield of 45%. The synthesis pathway of the above reaction was as follows:

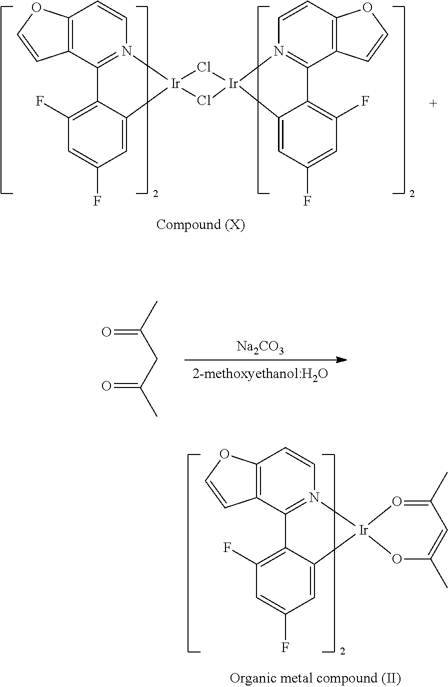

The physical measurement of Organic metal compound (II) is listed below: ¹H-NMR (200 MHz, CDCl₃, δ): 8.40-8.37 (d, 2H), 7.76-7.75 (m, 2H), 7.55 (m, 2H), 7.43-7.40 (d, 2H), 6.41-6.31 (m, 2H), 5.67-5.61 (m, 2H), 5.24 (s, 1H), 1.78 (s, 6H).

### EXAMPLE 3

### Preparation of Organic Metal Compound (III)

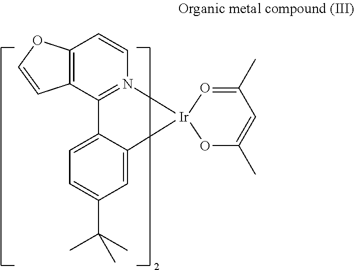

55.1 mmol of Compound (II), and 200 ml of water were added into the reaction bottle. Next, 82.5 mmol of 4-tert-Butylbenzoyl chloride was added into the reaction bottle at 0° C. After the addition was complete, sodium hydroxide aqueous solution (20 wt %) was added into the reaction bottle. After stirring for 8 hr, the mixture was filtrated, obtaining Compound (XI). The synthesis pathway of the above reaction was as follows:

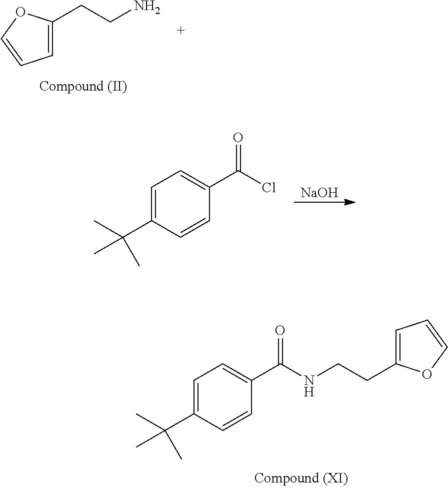

Next, 10 mmol of Compound (XI), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (XII) was obtained. The synthesis pathway of the above reaction was as follows:

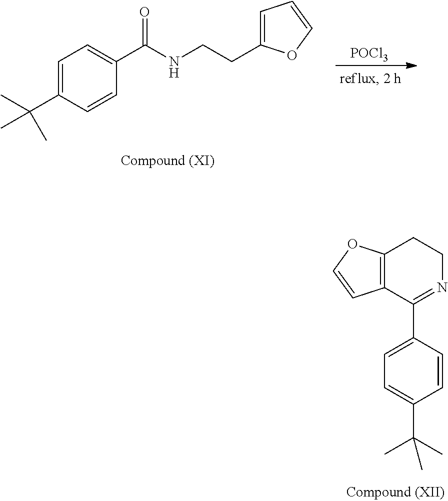

Next, 10 mmol of Compound (XII), 0.5 g of palladium 10% on carbon (Pd/C catalyst), and 100 ml of toluene were added into the reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (XIII) with a yield of 75%. The synthesis pathway of the above reaction was as follows:

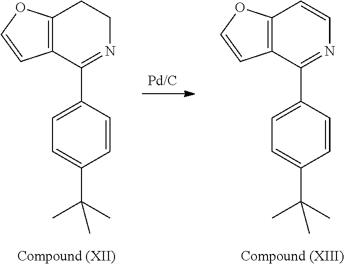 [SMILES: CC(C)(C)c1ccc(C2=NCCc3occc32)cc1 ; CC(C)(C)c1ccc(-c2nccc3occc23)cc1]

The physical measurement of Compound (XIII) is listed below: ¹H-NMR (200 MHz, CDCl₃, δ): 8.58-8.55 (d, 1H), 7.92-7.88 (d, 2H), 7.70-7.69 (m, 1H), 7.68 (m, 1H), 7.57-7.53 (d, 2H), 7.42-7.38 (d, 1H), 7.10-7.09 (s, 1H), 1.38 (s, 9H).

Next, 1.54 mmol of Compound (XIII), and 0.7 mmol of iridium trichloride (IrCl₃), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining Compound (XIV). The synthesis pathway of the above reaction was as follows:

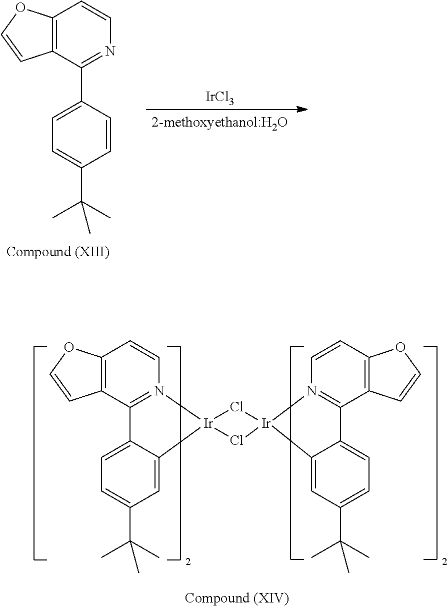

Next, 1 mmol of Compound (XIV), 3 mmol of acetylacetone, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (III) with a yield of 54%. The synthesis pathway of the above reaction was as follows:

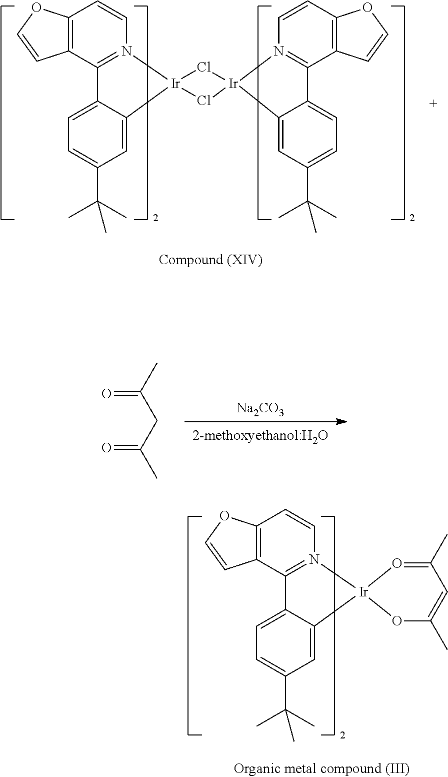

The physical measurement of Organic metal compound (III) is listed below ¹H-NMR (200 MHz, CDCl₃, δ): 8.44-8.41 (d, 2H), 7.83-7.78 (m, 4H), 7.50-7.49 (m, 2H), 7.35-7.32 (d, 2H), 6.92-6.87 (m, 2H), 6.22-6.21 (m, 2H), 5.29 (s, 1H), 1.77 (s, 6H), 0.99 (s, 9H).

### EXAMPLE 4

### Preparation of Organic Metal Compound (IV)

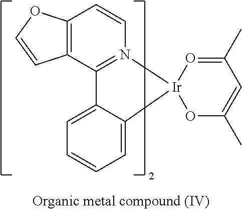

55.1 mmol of Compound (II), and 200 ml of water were added into the reaction bottle. Next, 82.5 mmol of benzoyl chloride was added into the reaction bottle at 0° C. After the addition was complete, sodium hydroxide aqueous solution (20 wt %) was added into the reaction bottle. After stirring for 8 hr, the mixture was filtrated, obtaining Compound (XV). The synthesis pathway of the above reaction was as follows:

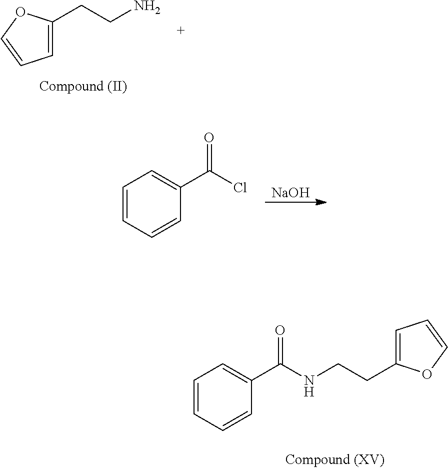

Next, 10 mmol Compound (XV), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (XVI) was obtained. The synthesis pathway of the above reaction was as follows:

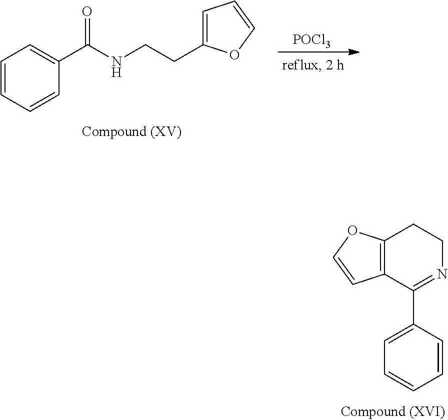

Next, Compound (XVI) (10 mmol), 0.5 g of palladium 10% on carbon (Pd/C catalyst), and 100 ml of toluene were added into the reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (XVII) with a yield of 96%. The synthesis pathway of the above reaction was as follows:

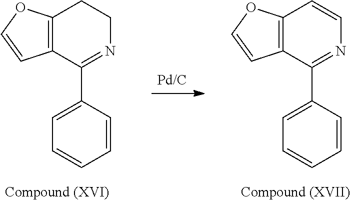 [SMILES: c1ccc(C2=NCCc3occc32)cc1 ; c1ccc(-c2nccc3occc23)cc1]

The physical measurement of Compound (XVII) is listed below: ¹H-NMR (200 MHz, CDCl₃, δ): 8.61 (d, 1H), 7.98-7.94 (d, 2H), 7.71-7.70 (s, 1H), 7.58-7.42 (m, 5H), 7.09 (s, 1H).

Next, 1.54 mmol of Compound (XVII), and 0.7 mmol of iridium trichloride (IrCl₃), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining Compound (XVIII). The synthesis pathway of the above reaction was as follows:

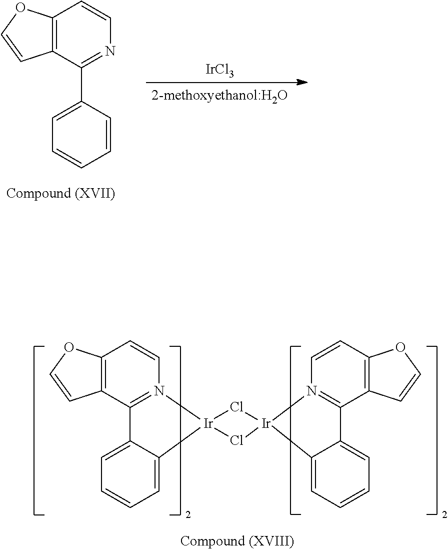

Next, 1 mmol of Compound (XVIII), 3 mmol of acetylacetone, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (IV) with a yield of 46%. The synthesis pathway of the above reaction was as follows:

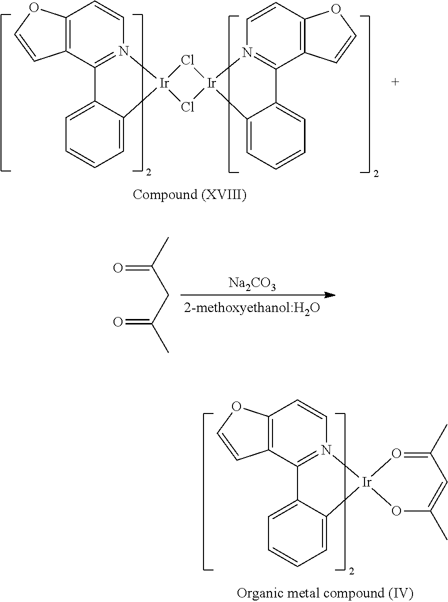

The physical measurement of Organic metal compound (IV) is listed below ¹H-NMR (200 MHz, CDCl₃, δ): 8.45-8.42 (d, 2H), 7.94-7.90 (d, 2H), 7.80 (m, 2H), 7.52 (m, 2H), 7.37-7.33 (d, 2H), 6.89-6.82 (t, 2H), 6.68-6.61 (t, 2H), 6.29-6.25 (d, 2H), 5.22 (s, 1H), 1.77 (s, 3H).

### EXAMPLE 5

### Preparation of Organic Metal Compound (V)

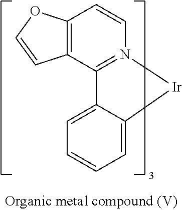

1 mmol of Organic metal compound (IV), 2 mmol of Compound (XVII), and 15 mL of glycerol were added into a reaction bottle. Next, after removing moisture and purging nitrogen gas several times, the reaction bottle was heated to 200° C. After reacting for 48 hr and cooling down to room temperature, the result was filtrated. The filter cake was collected and washed with water and dichloromethane, and then purified by column chromatography, obtaining Organic metal compound (V) with a yield of 47%. The synthesis pathway of the above reaction was as follows:

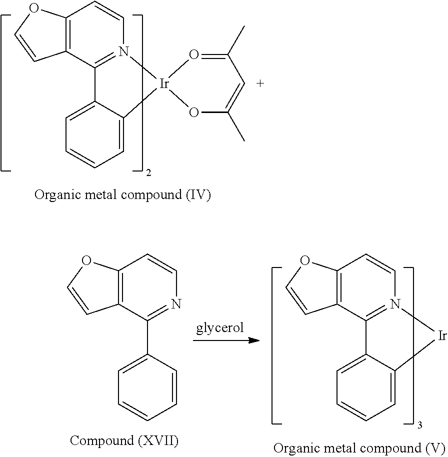

The physical measurement of Organic metal compound (V) is listed below ¹H-NMR (200 MHz, CDCl₃, δ): 8.05-8.02 (d, 3H), 7.73-7.72 (m, 3H), 7.54-7.40 (m, 3H), 7.40-7.37 (d, 3H), 7.05-6.82 (m, 12H).

### EXAMPLE 6

### Preparation of Organic Metal Compound (VI)

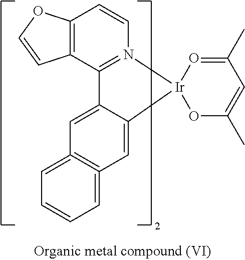

55.1 mmol of Compound (II), and 200 ml of water were added into the reaction bottle. Next, 82.5 mmol of 2-naphthoyl chloride were added into the reaction bottle at 0° C. After the addition was complete, sodium hydroxide aqueous solution (20 wt %) was added into the reaction bottle. After stirring for 8 hr, the mixture was filtrated, obtaining Compound (XIX). The synthesis pathway of the above reaction was as follows:

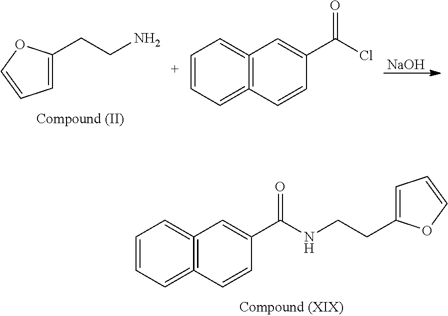

Next, 10 mmol of Compound (XIX), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (XX) is obtained. The synthesis pathway of the above reaction was as follows:

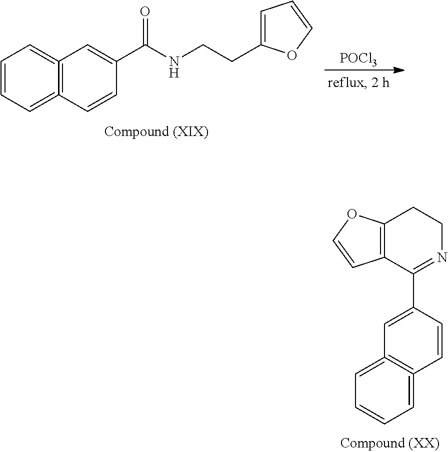

Next, 10 mmol of Compound (XX), 0.5 g of palladium 10% on carbon (Pd/C catalyst), and 100 ml of toluene were added into the reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (XXI) with a yield of 72%. The synthesis pathway of the above reaction was as follows:

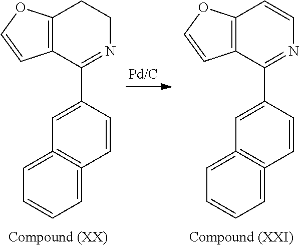

The physical measurement of Compound (XXI) is listed below: ¹H-NMR (200 MHz, CDCl₃, δ): 8.66-8.63 (d, 1H), 8.42 (s, 1H), 8.14-7.89 (m, 4H), 7.74-7.72 (d, 1H), 7.56-7.44 (m, 3H), 7.17 (s, 1H).

Next, Compound (XXI) (1.54 mmol), and 0.7 mmol of iridium trichloride (IrCl₃), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining Compound (XXII). The synthesis pathway of the above reaction was as follows:

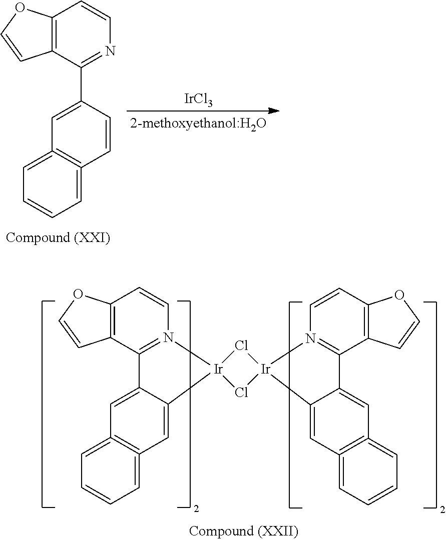

Next, 1 mmol of Compound (XXII), 3 mmol of acetylacetone, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (VI) with a yield of 48%. The synthesis pathway of the above reaction was as follows:

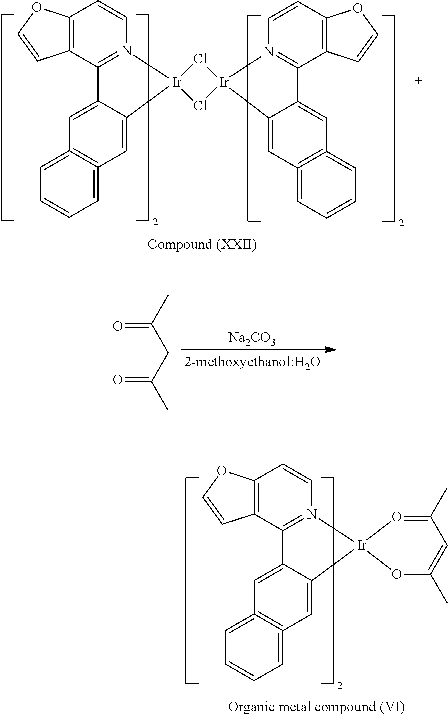

The physical measurement of Organic metal compound (VI) is listed below ¹H-NMR (200 MHz, CDCl₃, δ): 8.60-8.57 (d, 2H), 8.42 (s, 2H), 7.92 (m, 2H), 7.91 (m, 2H), 7.77-7.65 (m, 2H), 7.48-7.45 (d, 2H), 7.16-6.60 (m, 6H), 6.60 (s, 2H), 5.25 (s, 1H), 1.77 (s, 6H).

### EXAMPLE 7

### Preparation of Organic Metal Compound (VII)

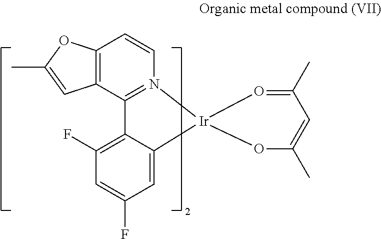

130 mmol of nitromethane, 52 mmol of 5-methyl-2-furaldehyde, and 10 ml methanol were added into a reaction bottle. Next, 130 mL of sodium hydroxide aqueous solution (1 M) were dropwisely added into the reaction bottle at 0° C. After stirring at 0° C. for 15 min, the mixture was added slowly into a hydrochloric acid aqueous solution (50 ml, 8 M). Next, the reaction was terminated after being checked by thin layer chromatography (TLC), and the result was added into a reaction bottle with CH₂Cl₂ and brine. After extracting, the organic phase was collected. Next, an organic phase was separated and concentrated, and then dried by anhydrous magnesium sulfate. Finally, the result was purified by column chromatography with petroleum ether and ethyl acetate, obtaining Compound (XXIII) with a yield of 70%.

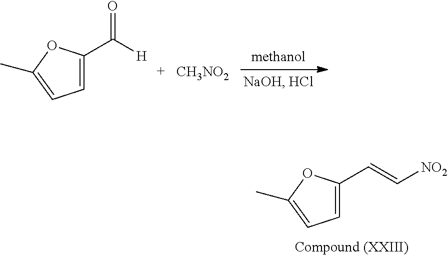

55.1 mmol of Compound (XXIII), and 200 ml of water were added into the reaction bottle. Next, 82.5 mmol of 2,4-difluorobenzoyl chloride was added into the reaction bottle at 0° C. After the addition was complete, sodium hydroxide aqueous solution (20 wt %) was added into the reaction bottle. After stirring for 8 hr, the mixture was filtrated, obtaining Compound (XXIV). The synthesis pathway of the above reaction was as follows:

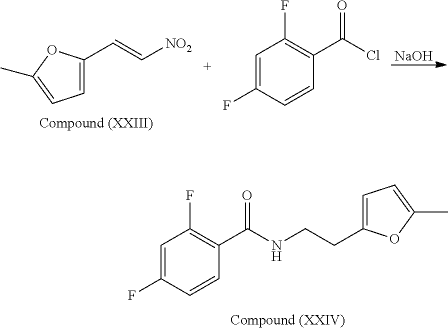

Next, 10 mmol of Compound (XXIV), 20 ml of toluene, and 3 mmol of phosphorus oxychloride (POCl₃) were added into the reaction bottle. After heating the reaction bottle for 2 hr, the mixture was neutralized by saturated sodium bicarbonate aqueous solution, and extracted with toluene. After concentrating, Compound (XXV) was obtained. The synthesis pathway of the above reaction was as follows:

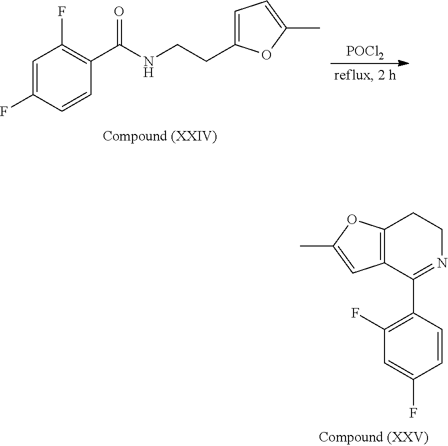

Next, 10 mmol of Compound (XXV), 0.5 g of palladium 10% on carbon (Pd/C catalyst), and 100 ml of toluene were added into the reaction bottle. Next, the reaction bottle was heated to reflux for 18 hr. Next, after removing Pd/C catalyst by filtration, the filtrate was extracted three times using ethyl acetate (EA) and water as the extraction solvent, and an organic phase was separated and concentrated, and then purified by column chromatography, obtaining Compound (XXVI) with a yield of 71%. The synthesis pathway of the above reaction was as follows:

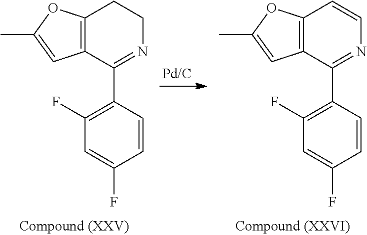 [SMILES: Cc1cc2c(o1)CCN=C2c1ccc(F)cc1F ; Cc1cc2c(-c3ccc(F)cc3F)nccc2o1]

The physical measurement of Compound (XXVI) is listed below: ¹H-NMR (200 MHz, CDCl₃, δ): 8.54-8.51 (d, 1H), 7.82-7.73 (q, 1H), 7.38-7.36 (d, 1H), 7.09-6.91 (m, 2H), 6.43-6.40 (d, 1H), 2.50 (s, 3H).

Next, 1.54 mmol of Compound (XXVI), and 0.7 mmol of iridium trichloride (IrCl₃), 15 ml of 2-methoxyethanol, and 5 ml of water were added into the reaction bottle. Next, after removing moisture and purging nitrogen gas several times, the reaction bottle was heated to reflux. After reacting for 24 hr and cooling down to room temperature, the result was filtrated. The filter cake was collected, washed with water and methanol, and dried, obtaining Compound (XXVII). The synthesis pathway of the above reaction was as follows:

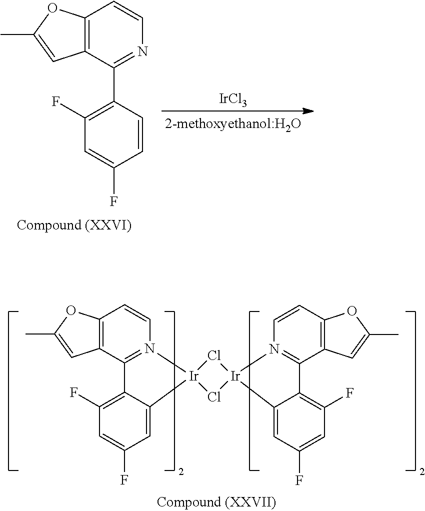

Next, 1 mmol of Compound (XXVII), 3 mmol of acetylacetone, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (VII) with a yield of 50%. The synthesis pathway of the above reaction was as follows:

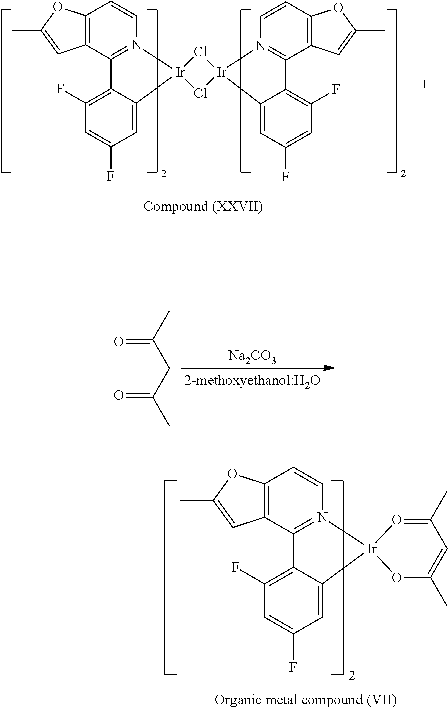

The physical measurement of Organic metal compound (VII) is listed below: ¹H-NMR (200 MHz, CDCl₃, δ): 8.33-8.30 (d, 2H), 7.32-7.28 (d, 2H), 7.14-7.12 (m, 2H), 6.39-6.26 (m, 2H), 5.64-5.59 (m, 2H), 5.23 (s, 1H), 2.58 (s, 6H), 1.77 (s, 6H).

### EXAMPLE 8

### Preparation of Organic Metal Compound (VIII)

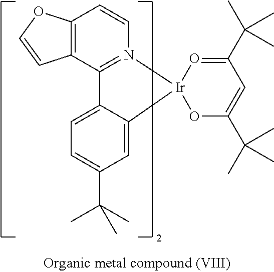

Next, 1 mmol of Compound (XIV), 3 mmol of 2,2,6,6-tetramethylheptane-3,5-dione, 2 mmol of sodium carbonate (Na₂CO₃), and 10 ml of 2-methoxyethanol were added into a reaction bottle. Next, after removing moisture and purging nitrogen gas several times, the reaction bottle was heated to 120° C. After reacting for 12 hr and cooling down to room temperature, the result was filtrated. The filter cake was collected and washed with water and hexane, and then dissolved in dichloromethane. Next, the solution was extracted three times using dichloromethane and water. Next, an organic phase was separated and concentrated, and then purified by column chromatography, obtaining Organic metal compound (VIII) with a yield of 56%. The synthesis pathway of the above reaction was as follows:

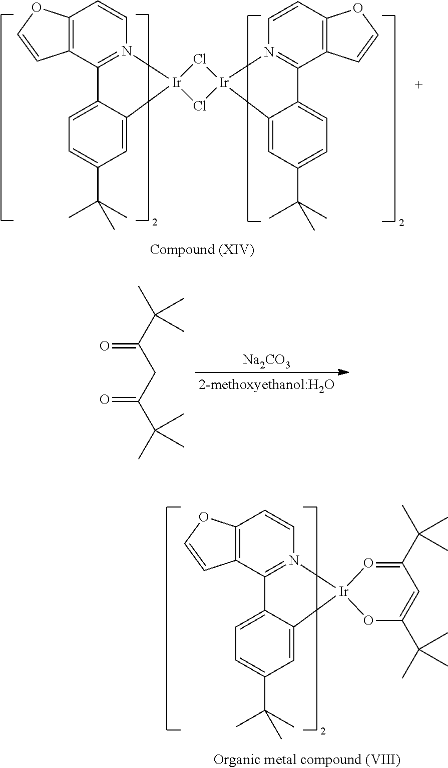

The physical measurement of Organic metal compound (VIII) is listed below ¹H-NMR (200 MHz, CDCl₃, δ): 8.34-8.31 (d, 2H), 7.83-7.75 (m, 4H), 7.50-7.49 (m, 2H), 7.26-7.23 (d, 2H), 6.91-6.86 (d, 2H), 6.36 (m, 2H), 5.44 (s, 1H), 1.52 (s, 9H), 1.02 (s, 9H), 0.95 (s, 9H).

### EXAMPLE 9

### Preparation of Organic Metal Compound (IX)

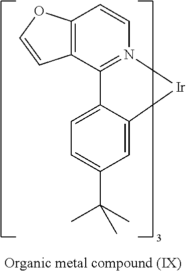

1 mmol of Organic metal compound (III), 1 mmol of Compound (XIII), and 15 mL of glycerol were added into a reaction bottle. Next, after removing moisture and purging nitrogen gas several times, the reaction bottle was heated to 200° C. After reacting for 48 hr and cooling down to room temperature, the result was filtrated. The filter cake was collected and washed with water and dichloromethane, and then purified by column chromatography, obtaining Organic metal compound (IX) with a yield of 35%. The synthesis pathway of the above reaction was as follows:

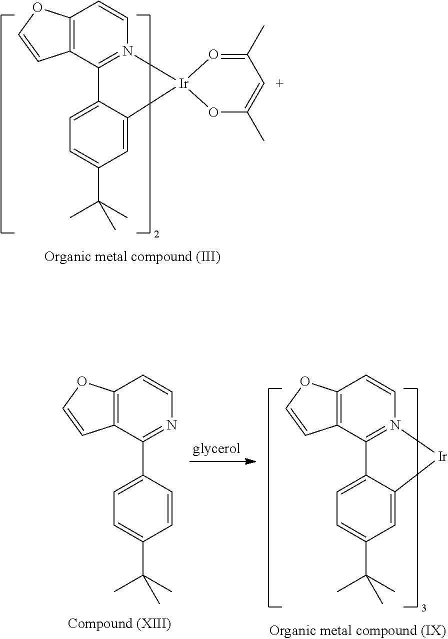

The physical measurement of Organic metal compound (IX) is listed below ¹H-NMR (200 MHz, CDCl₃, δ): 7.94-7.90 (d, 3H), 7.68 (d, 3H), 7.49 (d, 3H), 7.38-7.35 (d, 3H), 7.02-6.95 (m, 9H), 1.10 (s, 27H).

Due to the furopyridine derivative functional group, the organic metal compound having the structure of Formula (I) of the disclosure can serve as a dapant of the light emitting layer, resulting in the organic light-emitting device employing the organic metal compound of the disclosure having increased electron conductivity, high luminous efficiency, and improved life-time.

In addition, since the reactants and reagents for synthesizing the compound having furopyridine derivative functional group are dangerous and the steps are complicated time-consuming, it is generally considered that the compound having furopyridine derivative functional group is difficult to be synthesized. As a result, few reports on the research and development of the compound having furopyridine derivative functional group. The disclosure provides an iridium complex having furopyridine functional group and a process for preparing the iridium complex having furopyridine derivative functional group with a relatively high yield.

The conventional blue phosphorescent material FIr(pic) (having a structure represented by

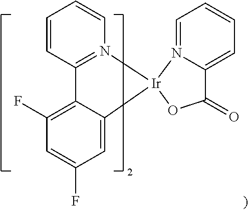

has a sublimation yield of about 50%. On the other hand, due to the furopyridine derivative functional group bonded to Ir, the organic metal compound having a structure of Formula (I) of the disclosure is suitable for being purified by a sublimation process (i.e. the organic metal compound having a structure of Formula (I) of the disclosure has a sublimation yield that is greater than 80%).

Organic Light-Emitting Device

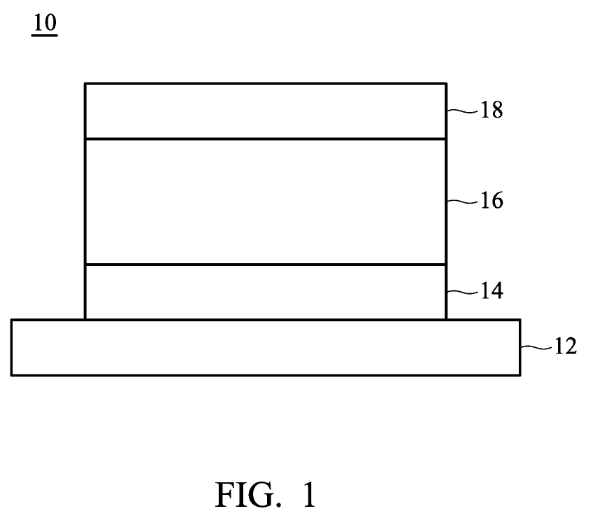

FIG. 1 shows an embodiment of an organic light-emitting device 10. The organic light-emitting device 10 includes a substrate 12, a bottom electrode 14, an organic light-emitting element 16, and a top electrode 18, as shown in FIG. 1. The organic light-emitting device can be a top-emission, bottom-emission, or dual-emission devices. The substrate 12 can be a glass, plastic, or semiconductor substrate. Suitable materials for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent.

The organic light-emitting element 16 at least includes an emission layer, and can further include a hole injection layer, a hole transport layer, an electron transport layer, and an electron injection layer. In an embodiment of the disclosure, at least one layer of the organic light-emitting element 16 includes the organic metal compound having a structure of Formula (I) of the disclosure.

According to another embodiment of the disclosure, the organic light-emitting device can be a phosphorescent organic light-emitting device, and the emission layer of the organic light-emitting element can include a host material and a dopant, wherein the dopant can include the organic metal compound having a structure of Formula (I) of the disclosure. The dose of the dopant is not limited and can be optionally modified by a person of ordinary skill in the field

In order to clearly disclose the organic light-emitting devices of the disclosure, the following examples (having an emitting layer employing the organic metal compounds of the disclosure formed by deposition (dry process) or coating (wet process)) are intended to illustrate the disclosure more fully without limiting their scope, since numerous modifications and variations will be apparent to those skilled in this art.

### EXAMPLE 10

### Organic Light-Emitting Device (I)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, TAPC (1,1-bis[4-[N,N′-di(p-tolyl)amino]phenyl]cyclobexane, with a thickness of 35 nm), TCTA (4,4′,4′-tri(N-carbazolyl)triphenylamine) doped with Organic metal compound (I) (the weight ratio between TCTA and Organic metal compound (I) was 94:6, with a thickness of 15 nm), TmPyPB (1,3,5-tri(m-pyrid-3-yl-phenyl)benzene, with a thickness of 42 nm), LiF (with a thickness of 0.5 nm), and Al (with a thickness of 120 nm), were subsequently formed on the PEDOT:PSS film at 10⁻⁶ torr, obtaining the organic light-emitting device (I) after encapsulation. The materials and layers formed therefrom are described in the following: ITO/PEDOT:PSS/TAPC/TCTA:organic metal compound (I) (6%)/TmPyPB/LiF/Al

Next, the optical properties (such as maximum emission peak, driving voltage, current efficiency, power efficiency, and C.I.E coordinate) of the light-emitting device (I) were measured by a spectra colorimeter PR650 (purchased from Photo Research Inc.) and a luminance meter LS110 (purchased from Konica Minolta). The results are shown in Table 1.

### EXAMPLE 11

### Organic Light-Emitting Device (II)

Example 11 was performed in the same manner as in Example 10 except that Organic metal compound (II) was substituted for Organic metal compound (I), obtaining the organic light-emitting device (II). The materials and layers formed therefrom are described in the following: ITO/PEDOT:PSS/TAPC/TCTA:Organic metal compound (II) (6%)/TmPyPB/LiF/Al

Next, the optical properties (such as maximum emission peak, driving voltage, current efficiency, power efficiency, and C.I.E coordinate) of the light-emitting device (II) were measured by a spectra colorimeter PR650 (purchased from Photo Research Inc.) and a luminance meter LS110 (purchased from Konica Minolta). The results are shown in Table 1.

### COMPARATIVE EXAMPLE 1

### Organic Light-Emitting Device (III)

Comparative Example 1 was performed in the same manner as in Example 10 except that compound (R1) (having a structure of

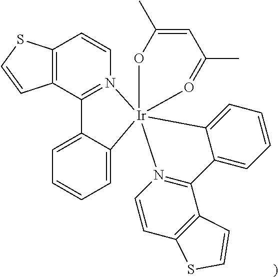

was substituted for Organic metal compound (I), obtaining the organic light-emitting device (III). The materials and layers formed therefrom are described in the following: ITO/PEDOT:PSS/TAPC/TCTA:compound (R1) (6%)/TmPyPB/LiF/Al

Next, the optical properties (such as maximum emission peak, driving voltage, current efficiency, power efficiency, and C.I.E coordinate) of the light-emitting device (III) were measured by a spectra colorimeter PR650 (purchased from Photo Research Inc.) and a luminance meter LS110 (purchased from Konica Minolta). The results are shown in Table 1.

### COMPARATIVE EXAMPLE 2

### Organic Light-Emitting Device (IV)

Comparative Example 2 was performed in the same manner as in Example 10 except that compound (R2) (having a structure of

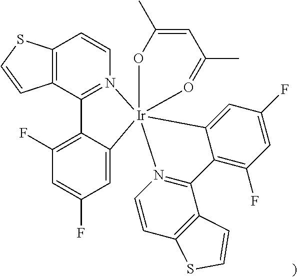

was substituted for Organic metal compound (I), obtaining the organic light-emitting device (IV). The materials and layers formed therefrom are described in the following: ITO/PEDOT:PSS/TAPC/TCTA:compound (R2) (6%)/TmPyPB/LiF/Al

Next, the optical properties (such as maximum emission peak, driving voltage, current efficiency, power efficiency, and C.I.E coordinate) of the light-emitting device (IV) were measured by a spectra colorimeter PR650 (purchased from Photo Research Inc.) and a luminance meter LS110 (purchased from Konica Minolta). The results are shown in Table 1.

### COMPARATIVE EXAMPLE 3

### Organic Light-Emitting Device (V)

Comparative Example 3 was performed in the same manner as in Example 10 except that Ir(ppy)₃ (having a structure of

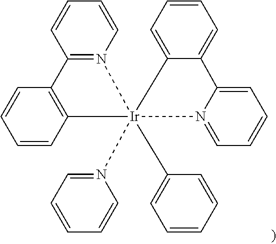

was substituted for Organic metal compound (I), obtaining the organic light-emitting device (V). The materials and layers formed therefrom are described in the following: ITO/PEDOT:PSS/TAPC/TCTA:Ir(ppy)₃ (6%)/TmPyPB/LiF/Al

Next, the optical properties (such as maximum emission peak, driving voltage, current efficiency, power efficiency, and C.I.E coordinate) of the light-emitting device (V) were measured by a spectra colorimeter PR650 (purchased from Photo Research Inc.) and a luminance meter LS110 (purchased from Konica Minolta). The results are shown in Table 1.

TABLE 1

| | | | | measured at | |
|---|---|---|---|---|---|
| | measured at | | | a brightness | |
| | a brightness | | | of 1000 Cd/m² | |
| | of 1000 Cd/m² | | | | maximum |
| | current | power | driving | | luminous |
| | efficiency | efficiency | voltage | C.I.E | intensity peak |
| | (cd/A) | (lm/W) | (V) | coordinate | (nm) |
| organic light-emitting | 91.6 | 86.9 | 3.4 | (0.40, 0.58) | 540 |
| device (I) | | | | | |
| organic light-emitting | 86.0 | 77.2 | 3.5 | (0.29, 0.62) | 504 |
| device (II) | | | | | |
| organic light-emitting | 74 | 58.2 | 4.0 | (0.47, 0.49) | 564 |
| device (III) | | | | | |
| organic light-emitting | 48.9 | 34.2 | 4.5 | (0.39, 0.58) | 528 |
| device (IV) | | | | | |
| organic light-emitting | 56.3 | 36.8 | 4.8 | (0.31, 0.62) | 516 |
| device (V) | | | | | |

As shown in Table 1, in comparison with the driving voltage of the organic light-emitting device (III) of Comparative Example 1, the organic light-emitting device (I) (employing the organic metal compound (I) as phosphorescent dopant) has a 0.6V decrease of driving voltage. Furthermore, the current efficiency of the organic light-emitting device (I) is about 1.2 times higher than that of the organic light-emitting device (III), and the power efficiency of the organic light-emitting device (I) is about 1.5 times higher than that of the organic light-emitting device (III).

### EXAMPLE 12

### Organic Light-Emitting Device (VI)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, a composition was used for forming a light-emitting layer coated on the PEDOT:PSS film by a blade coating process and baked at 100° C. for 40 min to form the light-emitting layer (with a thickness of 15 nm). The composition used for forming a light-emitting layer includes TCTA (4,4′,4′-tri(N-carbazolyl)triphenylamine) and Organic metal compound (I), wherein the weight ratio of TCTA and Organic metal compound (I) was 94:6, dissolved in chlorobenzene. Next, TmPyPB (1,3,5-tri(m-pyrid-3-yl-phenyl)benzene was coated on the light-emitting layer by a spin coating process to form a TmPyPB film (with a thickness of 50 nm). Next, LiF (with a thickness of 1 nm), and Al (with a thickness of 100 nm) were subsequently formed on the TmPyPB film at 10⁻⁶ torr, obtaining the organic light-emitting device (VI) after encapsulation. The materials and layers formed therefrom are described in the following: ITO/PEDOT:PSS/TCTA:Organic metal compound (I) (6%)/TmPyPB/LiF/Al.

Next, the optical properties (such as maximum emission peak, driving voltage, current efficiency, power efficiency, and C.I.E coordinate) of the light-emitting device (VI) were measured by a spectra colorimeter PR650 (purchased from Photo Research Inc.) and a luminance meter LS110 (purchased from Konica Minolta). The results are shown in Table 2.

### EXAMPLE 13

### Organic Light-Emitting Device (VII)

Example 13 was performed in the same manner as in Example 12 except that Organic metal compound (II) was substituted for Organic metal compound (I), obtaining the organic light-emitting device (VII). The materials and layers formed therefrom are described in the following: ITO/PEDOT:PSS/TCTA:Organic metal compound (II) (6%)/TmPyPB/LiF/Al.

Next, the optical properties (such as maximum emission peak, driving voltage, current efficiency, power efficiency, and C.I.E coordinate) of the light-emitting device (VII) were measured by a spectra colorimeter PR650 (purchased from Photo Research Inc.) and a luminance meter LS110 (purchased from Konica Minolta). The results are shown in Table 2.

### COMPARATIVE EXAMPLE 4

### Organic Light-Emitting Device (VIII)

Comparative Example 4 was performed in the same manner as in Example 12 except that compound (R1) (having a structure of

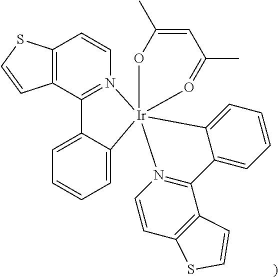

was substituted for Organic metal compound (I), obtaining the organic light-emitting device (VIII). The materials and layers formed therefrom are described in the following: ITO/PEDOT:PSS/TCTA:compound (R1) (6%)/TmPyPB/LiF/Al.

Next, the optical properties (such as maximum emission peak, driving voltage, current efficiency, power efficiency, and C.I.E coordinate) of the light-emitting device (VIII) were measured by a spectra colorimeter PR650 (purchased from Photo Research Inc.) and a luminance meter LS110 (purchased from Konica Minolta). The results are shown in Table 2.

### COMPARATIVE EXAMPLE 5

### Organic Light-Emitting Device (IX)

Comparative Example 5 was performed in the same manner as in Example 12 except that compound (R2) (having a structure of

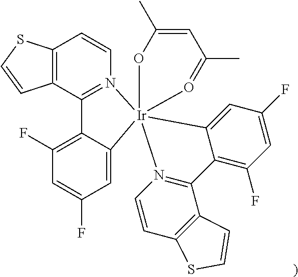

was substituted for Organic metal compound (I), obtaining the organic light-emitting device (IX). The materials and layers formed therefrom are described in the following: ITO/PEDOT:PSS/TCTA:compound (R2) (6%)/TmPyPB/LiF/Al.

Next, the optical properties (such as maximum emission peak, driving voltage, current efficiency, power efficiency, and C.I.E coordinate) of the light-emitting device (IX) were measured by a spectra colorimeter PR650 (purchased from Photo Research Inc.) and a luminance meter LS110 (purchased from Konica Minolta). The results are shown in Table 2.

TABLE 2

| | | | | measured at | |
|---|---|---|---|---|---|
| | measured at | | | a brightness | |
| | a brightness | | | of 1000 Cd/m² | |
| | of 1000 Cd/m² | | | | maximum |
| | current | power | driving | | luminous |
| | efficiency | efficiency | voltage | C.I.E | intensity peak |
| | (cd/A) | (lm/W) | (V) | coordinate | (nm) |
| organic light-emitting | 32.3 | 26.6 | 3.8 | (0.41, 0.58) | 540 |
| device (VI) | | | | | |
| organic light-emitting | 39.6 | 36.5 | 3.4 | (0.29, 0.62) | 504 |
| device (VII) | | | | | |
| organic light-emitting | 26.7 | 21.0 | 4.0 | (0.49, 0.51) | 560 |
| device (VIII) | | | | | |
| organic light-emitting | 35 | 25.9 | 4.3 | (0.39, 0.59) | 528 |
| device (IX) | | | | | |

As shown in Table 2, in comparison with the driving voltage of the organic light-emitting device (VIII) of Comparative Example 4, the organic light-emitting device (VI) (employing the organic metal compound (VI) as phosphorescent dopant) has a 0.2V decrease of driving voltage. Furthermore, the current efficiency and power efficiency of the organic light-emitting device (I) is about 1.2 times higher than that of the organic light-emitting device (VIII). In addition, in comparison with the driving voltage of the organic light-emitting device (IX) of Comparative Example 5, the organic light-emitting device (VII) (employing the organic metal compound (II) as phosphorescent dopant) has a 0.9V decrease of driving voltage. Furthermore, the current efficiency of the organic light-emitting device (VII) is about 1.1 times higher than that of the organic light-emitting device (IX), and the power efficiency of the organic light-emitting device (VII) is about 1.4 times higher than that of the organic light-emitting device (IX).

### EXAMPLE 14

### Organic Light-Emitting Device (X)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, TAPC (1,1-bis[4-[N,N′-di(p-tolyl)amino]phenyl]cyclobexane, with a thickness of 40 nm), NPB (N,N′-bis(naphthalen-1-yl)-N,N′-bis(phenyl)-benzidine) doped with Organic metal compound (VI) (the weight ratio between TCTA and Organic metal compound (VI) was 97:3˜96:4, with a thickness of 15 nm), TmPyPB (1,3,5-tri(m-pyrid-3-yl-phenyl)benzene, with a thickness of 50 nm), LiF (with a thickness of 0.8 nm), and Al (with a thickness of 120 nm), were subsequently formed on the PEDOT:PSS film at 10⁻⁶ torr, obtaining the organic light-emitting device (X) after encapsulation. The materials and layers formed therefrom are described in the following: ITO/PEDOT:PSS/TAPC/NPB:organic metal compound (VI) (3˜4%)/TmPyPB/LiF/Al.

Next, the optical properties (such as maximum emission peak, driving voltage, current efficiency, power efficiency, and C.I.E coordinate) of the light-emitting device (X) were measured by a spectra colorimeter PR650 (purchased from Photo Research Inc.) and a luminance meter LS110 (purchased from Konica Minolta). The results are shown in Table 3.

### EXAMPLE 15

### Organic Light-Emitting Device (XI)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, TAPC (1,1-bis[4-[N,N′-di(p-tolyl)amino]phenyl]cyclobexane, with a thickness of 40 nm), TCTA (4,4′,4′-tri(N-carbazolyl)triphenylamine) doped with Organic metal compound (VII) (the weight ratio between TCTA and Organic metal compound (VII) was 94:6˜92:8, with a thickness of 15 nm), TmPyPB (1,3,5-tri(m-pyrid-3-yl-phenyl)benzene, with a thickness of 50 nm), LiF (with a thickness of 0.8 nm), and Al (with a thickness of 120 nm), were subsequently formed on the PEDOT:PSS film at 10⁻⁶ torr, obtaining the organic light-emitting device (XI) after encapsulation. The materials and layers formed therefrom are described in the following: ITO/PEDOT:PSS/TAPC/TCTA:organic metal compound (VII) (6˜8%)/TmPyPB/LiF/Al.

Next, the optical properties (such as maximum emission peak, driving voltage, current efficiency, power efficiency, and C.I.E coordinate) of the light-emitting device (XI) were measured by a spectra colorimeter PR650 (purchased from Photo Research Inc.) and a luminance meter LS110 (purchased from Konica Minolta). The results are shown in Table 3.

### EXAMPLE 16

### Organic Light-Emitting Device (XII)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, TAPC (1,1-bis[4-[N,N′-di(p-tolyl)amino]phenyl]cyclobexane, with a thickness of 40 nm), NPB (N,N′-bis(naphthalen-1-yl)-N,N′-bis(phenyl)-benzidine) doped with Organic metal compound (VIII) (the weight ratio between NPB and Organic metal compound (VIII) was 95:5˜94:6, with a thickness of 15 nm), TmPyPB (1,3,5-tri(m-pyrid-3-yl-phenyl)benzene, with a thickness of 50 nm), LiF (with a thickness of 0.8 nm), and Al (with a thickness of 120 nm), were subsequently formed on the PEDOT:PSS film at 10⁻⁶ torr, obtaining the organic light-emitting device (XII) after encapsulation. The materials and layers formed therefrom are described in the following: ITO/PEDOT:PSS/NPB:organic metal compound (VIII) (5˜6%)/TmPyPB/LiF/Al.

Next, the optical properties (such as maximum emission peak, driving voltage, current efficiency, power efficiency, and C.I.E coordinate) of the light-emitting device (XII) were measured by a spectra colorimeter PR650 (purchased from Photo Research Inc.) and a luminance meter LS110 (purchased from Konica Minolta). The results are shown in Table 3.

### EXAMPLE 17

### Organic Light-Emitting Device (XIII)

A glass substrate with an indium tin oxide (ITO) film with a thickness of 120 nm was provided and then washed with a cleaning agent, acetone, and isopropanol with ultrasonic agitation. After drying with nitrogen flow, the ITO film was subjected to a UV/ozone treatment for 30 min.

Next, PEDOT:PSS (Poly(3,4-ethylenedioxythiophene)-poly(styrenesulfonate)) was coated on the ITO film by a spin coating process (with a rotation rate of 800 rpm for 3 sec and a rotation rate of 2000 rpm for 40 sec) and baked at 130° C. for 40 min to form a PEDOT:PSS film serving as a hole injection layer (with a thickness of 40 nm). Next, TAPC (1,1-bis[4-[N,N′-di(p-tolyl)amino]phenyl]cyclobexane, with a thickness of 40 nm), TCTA(4,4′,4′-tri(N-carbazolyl)triphenylamine) doped with Organic metal compound (IX) (the weight ratio between TCTA and Organic metal compound (IX) was 94:6˜92:8, with a thickness of 15 nm), TmPyPB (1,3,5-tri(m-pyrid-3-yl-phenyl)benzene, with a thickness of 50 nm), LiF (with a thickness of 0.8 nm), and Al (with a thickness of 120 nm), were subsequently formed on the PEDOT:PSS film at 10⁻⁶ torr, obtaining the organic light-emitting device (XIII) after encapsulation. The materials and layers formed therefrom are described in the following: ITO/PEDOT:PSS/TAPC/TCTA:organic metal compound (IX) (6˜8%)/TmPyPB/LiF/Al.

Next, the optical properties (such as maximum emission peak, driving voltage, current efficiency, power efficiency, and C.I.E coordinate) of the light-emitting device (XIII) were measured by a spectra colorimeter PR650 (purchased from Photo Research Inc.) and a luminance meter LS110 (purchased from Konica Minolta). The results are shown in Table 3.

TABLE 3

| | | | | measured at | |
|---|---|---|---|---|---|
| | measured at | | | a brightness | |
| | a brightness | | | of 1000 Cd/m² | |
| | of 1000 Cd/m² | | | | maximum |
| | current | power | driving | | luminous |
| | efficiency | efficiency | voltage | C.I.E | intensity peak |
| | (cd/A) | (lm/W) | (V) | coordinate | (nm) |
| organic light-emitting | 44.8 | 39.2 | 3.6 | (0.51, 0.46) | 580 |
| device (X) | | | | | |
| organic light-emitting | 86.6 | 73.8 | 3.7 | (0.28, 0.61) | 500 |
| device (XI) | | | | | |
| organic light-emitting | 64.0 | 53.8 | 3.75 | (0.42, 0.56) | 544 |
| device (XII) | | | | | |
| organic light-emitting | 86.6 | 68.3 | 4.08 | (0.41, 0.58) | 540 |
| device (XIII) | | | | | |

As shown in Table 3, during the formation of the light-emitting devices (X)-(XIII) via a dry process, it shows that the organic light-emitting device employing the organic metal compound having the structure of Formula (I) exhibits high luminous efficiency. Furthermore, the organic light-emitting device (XI) fabricated via the dry process has a current efficiency of 86.6 cd/A and a power efficiency of 73.8 lm/W.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organic metal compound, having a structure of Formula (I): 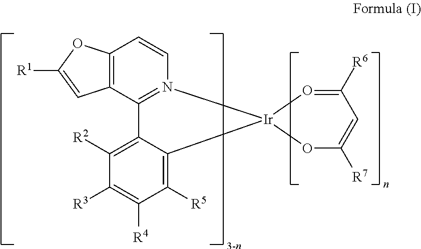
wherein, R¹ is independently hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R², R³, R⁴, and R⁵ are independently hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent C₁₋₆ alkyl group, or phenyl group; and, n is 0 or 1.

2. The organic metal compound as claimed in claim 1, wherein each R¹ is independently hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group.

3. The organic metal compound as claimed in claim 1, wherein R², R³, R⁴, and R⁵ are independently hydrogen, fluorine, methyl group, ethyl group, propyl group, isopropyl group, n-butyl group, isobutyl group, tert-butyl group, pentyl group, or hexyl group, or R³ and R⁴ are combined with the carbon atoms which they are attached to, to form a phenyl group.

4. The organic metal compound as claimed in claim 1, wherein at least one of R¹, R², R³, R⁴, and R⁵ is not hydrogen.

5. The organic metal compound as claimed in claim 1, wherein R⁶ and R⁷ are independently methyl group, ethyl group, propyl group, isopropyl group, n-butyl group, isobutyl group, tert-butyl group, pentyl group, hexyl group, or phenyl group.

6. The organic metal compound as claimed in claim 1, wherein the organic metal compound is 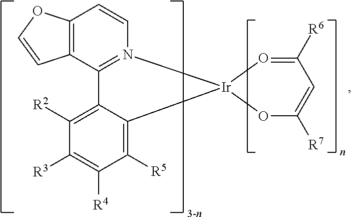
R², R³, R⁴, and R⁵ are independently hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group; R⁶ and R⁷ are independent C₁₋₆ alkyl group, or phenyl group; and, n is 0 or 1.

7. The organic metal compound as claimed in claim 6, wherein R², R³, R⁴, and R⁵ are independently hydrogen, fluorine, methyl group, ethyl group, propyl group, isopropyl group, n-butyl group, isobutyl group, tert-butyl group, pentyl group, or hexyl group, or R³ and R⁴ are combined with the carbon atoms which they are attached to, to form a phenyl group.

8. The organic metal compound as claimed in claim 6, wherein at least one of R², R³, R⁴, and R⁵ is not hydrogen.

9. The organic metal compound as claimed in claim 6, wherein R⁶ and R⁷ are independently methyl group, ethyl group, propyl group, isopropyl group, n-butyl group, isobutyl group, tert-butyl group, pentyl group, hexyl group, or phenyl group.

10. The organic metal compound as claimed in claim 1, wherein the organic metal compound is 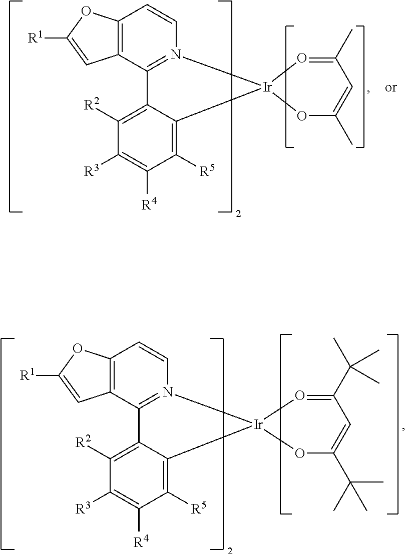
R¹ is independently hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; and, R², R³, R⁴, and R⁵ are independently hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group.

11. The organic metal compound as claimed in claim 10, wherein each R¹ is independently hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group.

12. The organic metal compound as claimed in claim 10, wherein R², R³, R⁴, and R⁵ are independently hydrogen, fluorine, methyl group, ethyl group, propyl group, isopropyl group, n-butyl group, isobutyl group, tert-butyl group, pentyl group, or hexyl group, or R³ and R⁴ are combined with the carbon atoms which they are attached to, to form a phenyl group.

13. The organic metal compound as claimed in claim 10, wherein at least one of R¹, R², R³, R⁴, and R⁵ is not hydrogen.

14. The organic metal compound as claimed in claim 1, wherein the organic metal compound is 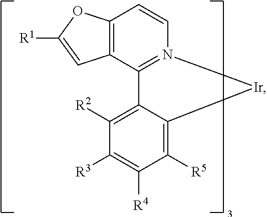
R¹ is independently hydrogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; and, R², R³, R⁴, and R⁵ are independently hydrogen, halogen, C₁₋₁₂ alkyl group, C₁₋₁₂ fluoroalkyl group, or two adjacent groups of R², R³, R⁴, and R⁵ are optionally combined with the carbon atoms which they are attached to, to form a cycloalkyl group, or aryl group.

15. The organic metal compound as claimed in claim 14, wherein each R¹ is independently hydrogen, methyl group, ethyl group, propyl group, isopropyl group, n-butyl group, isobutyl group, tert-butyl group, pentyl group, hexyl group, cyclohexyl group, phenyl group, biphenyl group, or naphthyl group.

16. The organic metal compound as claimed in claim 14, wherein R², R³, R⁴, and R⁵ are independently hydrogen, fluorine, methyl group, ethyl group, propyl group, isopropyl group, n-butyl group, isobutyl group, tert-butyl group, pentyl group, or hexyl group, or R³ and R⁴ are combined with the carbon atoms which they are attached to, to form a phenyl group.

17. The organic metal compound as claimed in claim 14, wherein at least one of R¹, R², R³, R⁴, and R⁵ is not hydrogen.

18. The organic metal compound as claimed in claim 1, wherein R¹ is independently hydrogen, or C₁₋₁₂ alkyl group; R², R³, R⁴, and R⁵ are independently hydrogen, halogen, C₁₋₁₂ alkyl group, or two adjacent groups of R², R³, R⁴, and R⁵ are optionally combined with the carbon atoms which they are attached to, to form an aryl group; R⁶ and R⁷ are independent C₁₋₆ alkyl group; and, n is 0 or 1.

19. The organic metal compound as claimed in claim 1, wherein the organic metal compound is

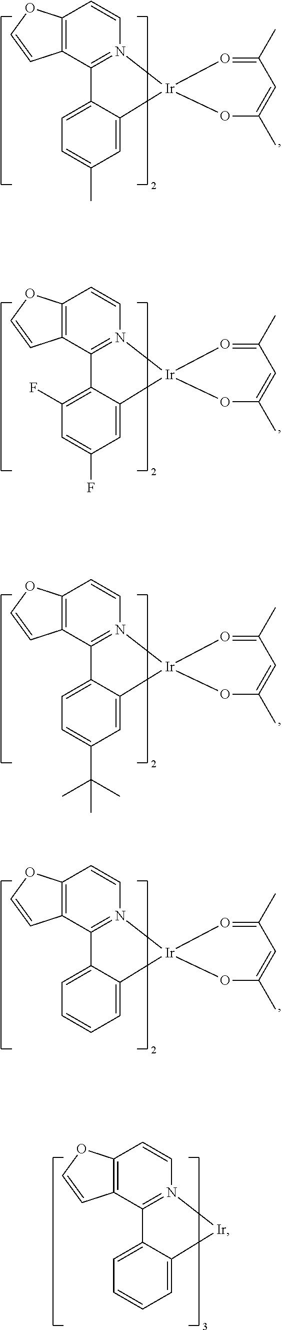

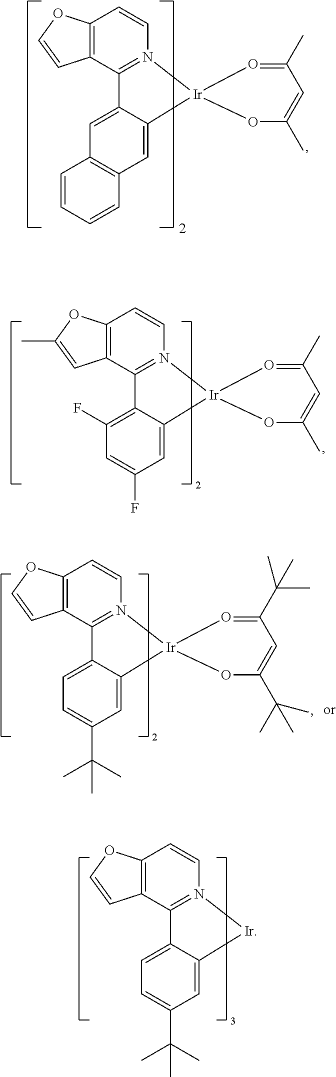

20. An organic light-emitting device, comprising:
a pair of electrodes; and
an organic light-emitting element, disposed between the electrodes, wherein the organic light-emitting element comprises the organic metal compound as claimed in claim 1.
